(19) United States
(12) Patent Application Publication
(10) Pub. No.: US 2016/0060757 A1
(43) Pub. Date: Mar. 3, 2016

(54) REACTOR OF SUBSTRATE PROCESSING APPARATUS

(71) Applicant: TERASEMICON CORPORATION, Hwaseong-si (KR)

(72) Inventors: Byung Il LEE, Seongnam-si (KR); Ho Young KANG, Hwaseong-si (KR)

(21) Appl. No.: 14/747,213

(22) Filed: Jun. 23, 2015

(30) Foreign Application Priority Data
Aug. 26, 2014 (KR) 10-2014-0111757

(51) Int. Cl. C23C 16/455

(52) U.S. Cl. CPC C23C 16/45544

(57) ABSTRACT

Provided is a reactor of a substrate processing apparatus. The reactor of the substrate processing apparatus is a reactor of a substrate processing apparatus for processing at least one substrate, the reactor having a horizontal cross-section provided in a shape having at least two curvature radii.

### CROSS-REFERENCE TO RELATED PATENT APPLICATION

This application claims the benefit of Korean Patent Application No. 10-2014-0111757, filed on Aug. 26, 2014, in the Korean Intellectual Property Office, the disclosure of which is incorporated herein in its entirety by reference.

### BACKGROUND

1. Field

The present invention relates to a reactor of a substrate processing apparatus and, more particularly, to a reactor of a substrate processing apparatus, capable of increasing uniformity of a substrate processing operation and increasing discharge efficiency of a substrate processing gas by providing a horizontal cross-section of the reactor in a shape having at least two curvature radii.

2. Description of the Related Art

A process for depositing a thin film on a substrate such as a silicon wafer is inevitably required to manufacture a semiconductor device. Schemes such as sputtering, chemical vapor deposition (CVD), atomic layer deposition (ALD), etc. are commonly used in the thin film deposition process.

The sputtering scheme is a technology for striking the surface of a target with argon ions generated in plasma state, and depositing a thin film on a substrate using a target material taken off from the surface of the target. The sputtering scheme may form a high-purity thin film having excellent adhesiveness, but may not form a fine pattern having a high aspect ratio.

The CVD scheme is a technology for injecting a variety of gases into a reaction chamber, allowing the gases induced by high energy such as heat, light or plasma to chemically react with a reaction gas, and thus depositing a thin film on a substrate. The CVD scheme may not easily control thermodynamic stability of atoms due to instantly occurring chemical reaction, and may reduce physical, chemical and electrical characteristics of the thin film.

The ALD scheme is a technology for alternately supplying a source gas, i.e., a reaction gas, and a purge gas and depositing a thin film on a substrate to a thickness of an atomic layer. Since surface reaction is used to overcome the limits of step coverage, the ALD scheme may be appropriately used to form a fine pattern having a high aspect ratio, and may achieve excellent electrical and physical characteristics of the thin film.

ALD apparatuses may be divided into a single-wafer-type ALD apparatus for loading a single substrate into a chamber at a time to perform a deposition process, and a batch-type ALD apparatus for loading a plurality of substrates into a chamber to perform a deposition process simultaneously on the substrates.

FIG. 1 is a perspective view of a conventional batch-type ALD apparatus.

FIG. 2 is a horizontal cross-sectional view showing the flow of a substrate processing gas in the conventional batch-type ALD apparatus.

Referring to FIGS. 1 and 2, the conventional batch-type ALD apparatus includes a process tube 10 for providing a chamber 11 corresponding to a space where substrates 40 are loaded and deposition operation is performed. Components necessary for the deposition operation, e.g., a gas supplier 20 and a gas discharger 30, are provided in the process tube 10. The conventional batch-type ALD apparatus also includes a base 51 tightly coupled to the process tube 10, a protrusion 53 inserted into the process tube 10, and a boat 50 including support bars 55 to stack a plurality of substrates 40.

In this conventional batch-type ALD apparatus, the process tube 10 has a circular horizontal cross-section as illustrated in FIG. 2. Furthermore, the gas supplier 20 and the gas discharger 30 are provided at two ends to face each other. The substrate processing gas supplied from the gas supplier 20 into the chamber 11 in a substrate processing operation may immediately flow to and discharged through the gas discharger 30 along path 1, or may be reflected on an inner wall of the process tube 10 and discharged through the gas discharger 30 along path 2. However, if the substrate processing gas is supplied at a small incident angle on the inner wall of the process tube 10 as indicated by path 3, or supplied at a large incident angle on the inner wall of the process tube 10 as indicated by path 4, the substrate processing gas may not immediately discharged through the gas discharger 30 but may be reflected and convected in the chamber 11 before being discharged. This is because sums P′, P″ and P′″ of incident angles and reflection angles of paths 2, 3 and 4 are different from each other.

When the substrate processing gas is not immediately discharged but is reflected in the chamber 11 as indicated by path 3 or 4, since the substrate processing gas additionally reacts with the substrates 40 and thus deposition is further performed on only a specific part of the substrates 40, deposition uniformity of the substrates 40 may be reduced.

Furthermore, in the conventional batch-type ALD apparatus, since the process tube 10 has a circular horizontal cross-section, the gas discharger 30 is providable only in a space 31 between a part outside the substrates 40 [or the protrusion 53 of the substrate loader 50] and the inner wall of the process tube 10 based on the horizontal cross-section. As such, to achieve cost reduction by reducing the chamber 11 in volume and reducing the amount of a process gas supplied into the chamber 11, the size of a space occupied by the gas discharger 30 should be reduced. For example, the number of gas discharge tubes (not shown) included in the gas discharger 30 should be reduced, or a diameter of the gas discharge tubes should be reduced. Accordingly, discharge efficiency of the gas discharged by the gas discharger 30 provided in the narrow space 31 is low.

Meanwhile, in general, the conventional ALD apparatus uses the bell-shaped process tube 10 as an ideal shape to easily resist pressure inside the chamber 11. However, due to an upper space 12 of the bell-shaped chamber 11, much time is required to supply and discharge a process gas, and the process gas is wasted.

### SUMMARY

An embodiment of the present invention provides a reactor of a substrate processing apparatus, capable of increasing discharge efficiency of a substrate processing gas by providing a horizontal cross-section of the reactor for processing substrates, in a shape having at least two curvature radii.

An embodiment of the present invention also provides a reactor of a substrate processing apparatus, capable of increasing deposition uniformity of substrates by allowing a substrate processing gas to be discharged immediately after deposition reaction with the substrates.

An embodiment of the present invention also provides a reactor of a substrate processing apparatus, capable of reducing an internal space of the reactor by modifying a top surface of the reactor from a bell shape into a flat shape.

According to an aspect of the present invention, there is provided a reactor of a substrate processing apparatus for processing at least one substrate, the reactor having a horizontal cross section provided in a shape having at least two curvature radii.

According to another aspect of the present invention, there is provided a reactor of a substrate processing apparatus for processing at least one substrate, the reactor having a horizontal cross section provided in a shape of at least two arcs having curvature radii greater than a diameter of the substrate.

According to another aspect of the present invention, there is provided a reactor of a substrate processing apparatus for processing at least one substrate, the reactor having a horizontal cross section provided in a shape of an oval having a minor axis greater than a diameter of the substrate.

### BRIEF DESCRIPTION OF THE DRAWINGS

The above and other features and advantages of the present invention will become more apparent by describing in detail embodiments thereof with reference to the attached drawings in which:

FIG. 1 is a perspective view of a conventional batch-type atomic layer deposition (ALD) apparatus;

FIG. 2 is a horizontal cross-sectional view showing the flow of a substrate processing gas in the conventional batch-type ALD apparatus;

FIG. 3 is a perspective view of a substrate processing apparatus according to an embodiment of the present invention;

FIGS. 4 to 8 are horizontal cross-sectional views of reactors according to various embodiments of the present invention; and

FIG. 9 shows perspective views of a plurality of reinforcing ribs coupled to a top surface of a reactor, according to embodiments of the present invention.

### DETAILED DESCRIPTION OF THE INVENTION

The present invention now will be described more fully hereinafter with reference to the accompanying figures, in which embodiments of the invention are shown. The present invention may, however, be embodied in many alternate forms and should not be construed as limited to the embodiments set forth herein. Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like numbers refer to like elements throughout the description of the figures. In the drawings, the thickness of layers and regions are exaggerated for clarity.

In this specification, substrates may be understood to include semiconductor substrates, substrates used in display devices such as LED and LCD, solar cell substrates, etc.

Furthermore, in this specification, a substrate processing operation refers to a deposition process and, more particularly, to a deposition process using atomic layer deposition (ALD). However, the substrate processing operation is not limited thereto and may be understood to include a deposition process using chemical vapor deposition (CVD), a heat treatment process, etc. The deposition process using ALD is assumed in the following description.

A batch-type apparatus according to embodiments of the present invention is now described in detail with reference to the attached drawings.

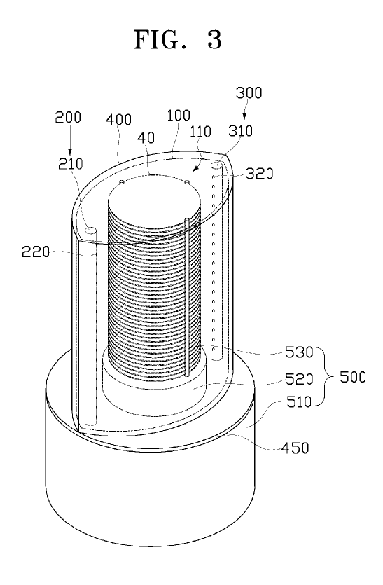

FIG. 3 is a perspective view of a substrate processing apparatus according to an embodiment of the present invention.

Referring to FIG. 3, the substrate processing apparatus according to the current embodiment may include a reactor 100, a housing 400 and a substrate loader 500.

The reactor 100 functions as a process tube, accommodates a substrate loader 500 on which a plurality of substrates 40 are stacked, and provides a substrate processor 110. The substrate processor 110 is a chamber capable of performing a substrate processing operation such as a deposition layer forming operation.

The material of the reactor 100 may be at least one of quartz, stainless steel (SUS), aluminium, graphite, silicon carbide and aluminium oxide.

The reactor 100 may include the substrate processor 110, which is a chamber for processing the substrates 40, a gas supplier 200 for supplying a substrate processing gas into the substrate processor 110, and a gas discharger 300 for discharging the substrate processing gas supplied into the substrate processor 110.

The gas supplier 200 may include at least one gas supply tube 210 provided along a length direction (i.e., vertical direction in FIG. 3) of the gas supplier 200. Here, the gas supply tube 210 is not limited to the tube shape illustrated in FIG. 3, and may have another shape, e.g., a hole, as long as the gas supply tube 210 may function as a path for receiving the substrate processing gas from the outside of the reactor 100 and supplying the same into the substrate processor 110. However, the gas supply tube 210 may be configured as a tube to accurately control the amount of the supplied substrate processing gas. In addition, although the gas supplier 200 includes one gas supply tube 210 in FIG. 3, the number of gas supply tubes 210 is appropriately variable.

A plurality of supply holes 220 may be provided at a side of the gas supply tube 210 toward the substrates 40 located in the substrate processor 110.

The gas discharger 300 may include at least one gas discharge tube 310 provided along a length direction (i.e., vertical direction in FIG. 3) of the gas discharger 300. Here, the gas discharge tube 310 is not limited to the tube shape illustrated in FIG. 3, and may have another shape, e.g., a hole, as long as the gas discharge tube 310 may function as a path for discharging the substrate processing gas inside the substrate processor 110 to the outside of the reactor 100. The gas discharge tube 310 may be configured as a tube having a diameter greater than that of the gas supply tube 210 to appropriately discharge the substrate processing gas. Instead of the gas discharge tube 310, the gas discharger 300 may include a discharge channel (not shown) having holes for discharging the substrate processing gas, to discharge the substrate processing gas using a pump connected to an end of the discharge channel. In addition, although the gas discharger 300 includes one gas discharge tube 310 in FIG. 3, the number of gas discharge tubes 310 is appropriately variable.

A plurality of discharge holes 320 may be provided at a side of the gas discharge tube 310 toward the substrates 40 located in the substrate processor 110.

The supply holes 220 and the discharge holes 320 may be located to correspond to spaces between the adjacent substrates 40 supported by a plurality of substrate supports 530 when the substrate loader 500 is coupled to a manifold 450 and thus the substrates 40 are accommodated in the substrate processor 110, in such a manner that the substrate processing gas is uniformly supplied between the substrates 40 and easily sucked and discharged to the outside.

The housing 400 has an open bottom, and may have a shape corresponding to the reactor 100 to surround the reactor 100. A top surface of the housing 400 may be supported by a top surface of a process room (not shown) such as a clean room. The outermost surface of the housing 400 may be provided with SUS, aluminium, or the like, and a heater (not shown) including sequentially connected bent parts (e.g., “∪” or “∩” shapes) may be provided on an internal side surface of the housing 400.

The substrate loader 500 is provided to be liftable by a known elevator system (not shown), and may include a main base 510, an auxiliary base 520 and the substrate supports 530.

The main base 510 is provided in a substantially cylindrical shape and may be mounted on a bottom surface of the process room, and a top surface of the main base 510 may be tightly coupled to the manifold 450 which is coupled to a lower part of the housing 400.

The auxiliary base 520 is provided in an almost cylindrical shape, is mounted on the top surface of the main base 510, and may be inserted into the substrate processor 110 of the reactor 100. The auxiliary base 520 may be rotatably provided in association with a motor (not shown) to rotate the substrates 40 in the substrate processing operation and to achieve uniformity of a semiconductor manufacturing process. In addition, an auxiliary heater (not shown) for applying heat from under the substrates 40 in the substrate processing operation may be included in the auxiliary base 520 to achieve reliability of the operation. The substrates 40 stacked and stored on the substrate loader 500 may be preheated by the auxiliary heater before the substrate processing operation.

The substrate supports 530 may be provided at certain intervals along an edge of the auxiliary base 520. A plurality of support grooves may be provided at inner sides of the substrate support 530 toward the central axis of the auxiliary base 520 to correspond to each other. Edges of the substrates 40 are inserted into and supported by the support grooves, and thus the substrates 40 may be vertically stacked and stored on the substrate loader 500.

The substrate loader 500 may be lifted to be detachably coupled to a bottom surface of the manifold 450 having a top surface coupled to a bottom surface of the reactor 100 and bottom surfaces of the gas supplier 200 and the gas discharger 300. The gas supply tube 210 of the gas supplier 200 may be inserted into a gas supply connection hole (not shown) of the manifold 450 to be connected to an external gas supply device, and the gas discharge tube 310 of the gas discharger 300 may be inserted into a gas discharge connection hole (not shown) of the manifold 450 to be connected to an external gas discharge device.

When the substrate loader 500 is lifted and thus the top surface of the main base 510 of the substrate loader 500 is coupled to the bottom surface of the manifold 450, the substrates 40 may be loaded into the substrate processor 110 and the substrate processor 110 may be sealed. For stable sealing, a sealing member (not shown) may be provided between the manifold 450 and the main base 510 of the substrate loader 500.

The embodiment of the present invention is characterized in that a horizontal cross-section of the reactor 100 has at least two curvature radii. This means that multiple arcs having different curvatures are continuously connected to each other to form the horizontal cross-section of the reactor 100.

The embodiment of the present invention is also characterized in that the horizontal cross-section of the reactor 100 is provided in a shape in which at least two arcs having curvature radii greater than a diameter of the substrates 40 contact each other.

The embodiment of the present invention is further characterized in that the horizontal cross-section of the reactor 100 is provided in a shape of an oval having a minor axis greater than the diameter of the substrates 40.

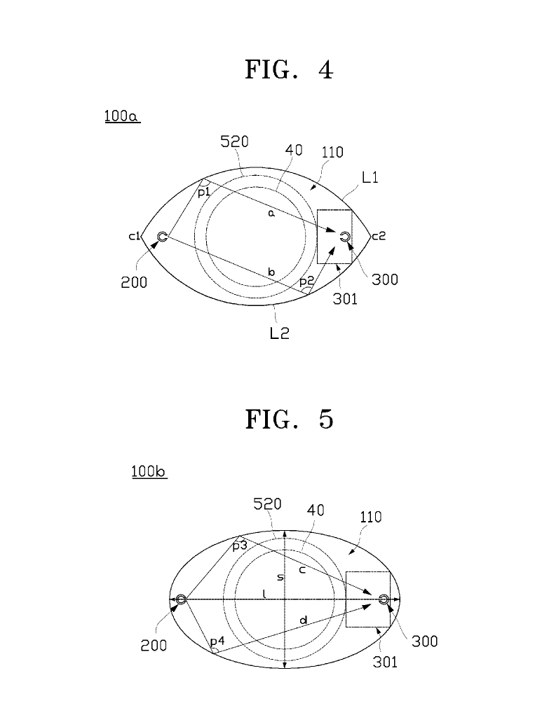

FIGS. 4 to 8 are horizontal cross-sectional views of reactors 100: 100a, 100b, 100c, 100d and 100e according to various embodiments of the present invention.

Referring to FIG. 4, a horizontal cross-section of the reactor 100a may be provided in a shape in which two arcs L1 and L2 having curvature radii greater than the diameter of the substrates 40 contact each other at points c1 and c2.

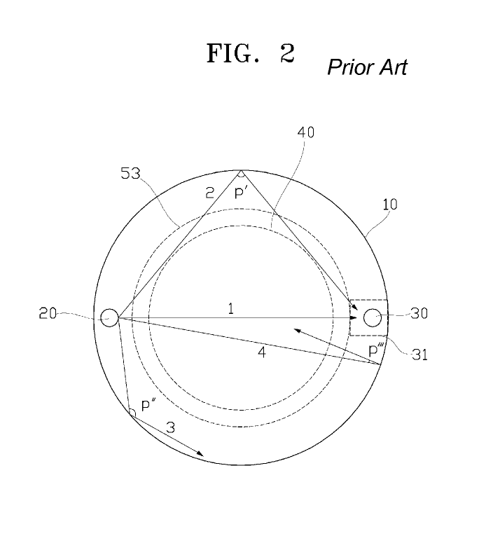

Unlike the conventional process tube 10 illustrated in FIG. 2 and having a circular horizontal cross-section, in the reactor 100a, the gas supplied from the gas supplier 200 at any incidence angle on an inner wall of the reactor 100a may be reflected on the inner wall of the reactor 100a to proceed toward the gas discharger 300 along path a or b. This is because a sum of an incidence angle of the gas supplied from the gas supplier 200 on the inner wall of the reactor 100a, and a reflection angle of the gas on the inner wall of the reactor 100a is constant. In other words, sum p1 of an incident angle and a reflection angle of the path a may be substantially equal to sum p2 of an incident angle and a reflection angle of the path b.

The sum of the incident angle and the reflection angle is constant because, since the horizontal cross-section of the reactor 100a is provided in a shape close to an oval and the gas supplier 200 and the gas discharger 300 are provided close to focuses of the oval, the characteristic of ovals in that an angle formed between a specific point on an oval and two focuses of the oval is constant may be similarly applied thereto.

Referring to FIG. 5, a horizontal cross-section of the reactor 100b may be provided in a shape of an oval having a minor axis s greater than the diameter of the substrates 40. In FIG. 5, since the minor axis s of the oval corresponds to a vertical length of the reactor 100b while a major axis I of the oval corresponds to a horizontal length of the reactor 100b, the major axis I of the oval is obviously greater than the diameter of the substrates 40 and the minor axis s of the oval. The oval may be interpreted as a shape in which an infinite number of arcs having different curvature radii are continuously connected to each other.

Unlike the conventional process tube 10 illustrated in FIG. 2 and having a circular horizontal cross-section, in the reactor 100b, the gas supplied from the gas supplier 200 at any incidence angle on an inner wall of the reactor 100b may be reflected on the inner wall of the reactor 100b to proceed toward the gas discharger 300 along path c or d. This is because a sum of an incidence angle of the gas supplied from the gas supplier 200 on the inner wall of the reactor 100b, and a reflection angle of the gas on the inner wall of the reactor 100a is constant. In other words, sum p3 of an incident angle and a reflection angle of the path c may be substantially equal to sum p4 of an incident angle and a reflection angle of the path d.

The sum of the incident angle and the reflection angle is constant because, since the horizontal cross-section of the reactor 100b is provided in a shape of an oval and the gas supplier 200 and the gas discharger 300 are provided close to focuses of the oval, the characteristic of ovals in that an angle formed between a specific point on an oval and two focuses of the oval is constant may be equally applied thereto.

Referring to FIG. 6, a horizontal cross-section of the reactor 100c is provided in a shape in which only two end parts of the shape illustrated in FIG. 4 or 5 are changed into straight lines L4. That is, parts L3 other than the straight lines L4 at the two end parts may be provided in a shape of two arcs or an oval having curvature radii (or radius) greater than the diameter of the substrates 40.

Based on the same principle of the above-described reactor 100a or 100b, in the reactor 100c, sum p5 of an incident angle and a reflection angle of path e may be substantially equal to sum p6 of an incident angle and a reflection angle of path f, and the gas supplied from the gas supplier 200 at any incidence angle on an inner wall of the reactor 100c may be reflected on the inner wall of the reactor 100c to proceed toward the gas discharger 300 along the path e or f.

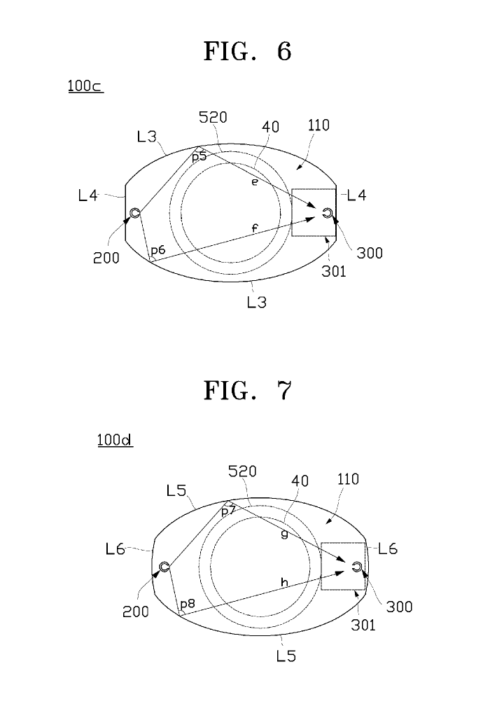

Referring to FIG. 7, a horizontal cross-section of the reactor 100d is provided in a shape in which two end parts of the shape illustrated in FIG. 4 or 5 are changed into arcs L6. That is, the arcs L6 at the two end parts and parts L5 other than the arcs L6 may be provided in a shape of four arcs or an oval having curvature radii (or radius) greater than the diameter of the substrates 40. In this case, the four arcs L5 and L6 may have equal or different curvatures.

Based on the same principle of the above-described reactor 100a or 100b, in the reactor 100d, sum p7 of an incident angle and a reflection angle on path g may be substantially equal to sum p8 of an incident angle and a reflection angle of path h, and the gas supplied from the gas supplier 200 at any incidence angle of an inner wall of the reactor 100d may be reflected on the inner wall of the reactor 100d to proceed toward the gas discharger 300 along the path g or h.

As described above, in the reactor 100 according to the present embodiment, since the gas supplied from the gas supplier 200 is continuously convected in the substrate processor 110 to avoid retention thereof and is discharged through the gas discharger 300 immediately after deposition reaction with the substrates 40, discharge efficiency of the substrate processing gas may be increased.

In addition, since the gas supplied from the gas supplier 200 is continuously convected to avoid retention thereof and is immediately discharged through the gas discharger 300, deposition may not be concentrated on a specific part of the substrates 40 and may be performed on the entire substrates 40 to a uniform thickness.

Meanwhile, unlike the conventional process tube 10 illustrated in FIG. 2 and having a circular horizontal cross-section, according to the embodiment of the present invention, a space 301 for the gas discharger 300 may be much larger. Based on the horizontal cross-sections thereof, the gas discharger 30 is providable in the space 31 between a part outside the substrates 40 [or the protrusion 53 of the substrate loader 50] and the inner wall of the process tube 10 in the conventional process tube 10, but the gas discharger 30 is providable in the space 301 between a part outside the substrates 40 [or the auxiliary base 520 of the substrate loader 500] facing the gas supplier 200, and the inner wall of the reactor 100 in the reactor 100 according to the embodiment of the present invention. Since the space 301 is a wide space having a horizontal length greater than that of the space 31, the number or diameter of the gas discharge tubes 310 may be increased compared to the conventional gas discharger 30 [see FIG. 2]. Accordingly, discharge efficiency of the substrate processing gas may be increased.

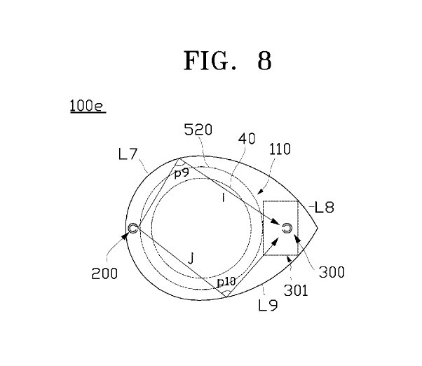

Referring to FIG. 8, a horizontal cross-section of the reactor 100e may be provided in a shape divided into a left half having the circular shape of the conventional process tube 10 and a right half having the shape of FIG. 4 or 5. That is, parts L8 and L9 other than a circular arc L7 may be provided in a shape of two arcs or an oval having curvature radii (or radius) greater than the diameter of the substrates 40.

Unlike the reactors 100a, 100b, 100c and 100d, in the reactor 100e, although sum p9 of an incident angle and a reflection angle of path i may not be equal to sum p10 of an incident angle and a reflection angle of path j, since the space 301 where the gas discharger 300 is providable is large, discharge efficiency of the substrate processing gas may be increased.

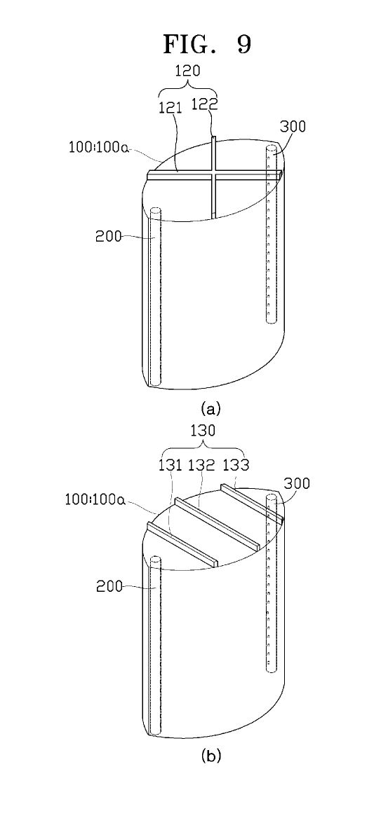

FIG. 9 shows perspective views of a plurality of reinforcing ribs 120 or 130 coupled to a top surface of the reactor 100, according to embodiments of the present invention.

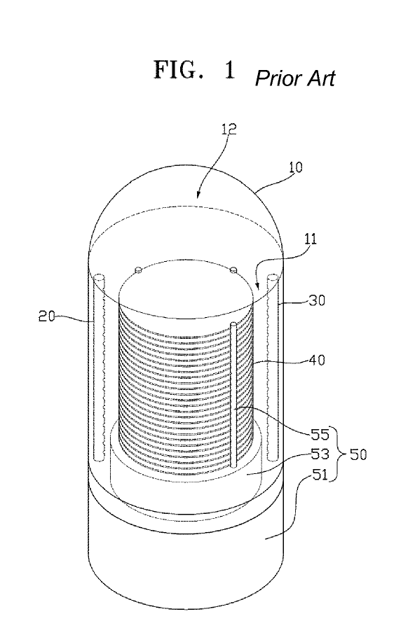

Unlike the bell-shaped process tube 10 of the conventional batch-type substrate processing apparatus illustrated in FIG. 1, the reactor 100 according to the embodiment of the present invention may have a flat top surface. Since the top surface of the reactor 100 is flat and thus the upper space 12 of the bell-shaped chamber 11 (see FIG. 1) incapable of accommodating the substrates 40 is not necessary, the substrate processor 110 of the reactor 100 may be reduced in volume. However, to solve a problem in durability which can be caused because internal pressure is not uniformly distributed compared to the conventional bell-shaped chamber 11, the batch-type substrate processing apparatus according to the embodiment of the present invention is characterized in that the reinforcing ribs 120 or 130 are coupled to the top surface of the reactor 100.

The reinforcing ribs 120 or 130 may use the same material as the reactor 100, but are not limited thereto. A variety of materials appropriate to support the top surface of the reactor 100 may be used.

The reinforcing ribs 120 or 130 may be coupled to the top surface of the reactor 100 by providing a plurality of reinforcing ribs 121 and 122 to cross each other as illustrated in (a) of FIG. 9, or by providing a plurality of reinforcing ribs 131, 132 and 133 to be parallel with each other as illustrated in (b) of FIG. 9. The reinforcing ribs 120 or 130 may be coupled to the top surface of the reactor 100 using, for example, welding.

As described above, according to the embodiment of the present invention, discharge efficiency of a substrate processing gas may be increased by providing a horizontal cross-section of the reactor 100 in a shape having at least two curvature radii. Furthermore, deposition uniformity of the substrates 40 may be increased by allowing the substrate processing gas to be discharged immediately after deposition reaction with the substrates 40.

In addition, the size of an internal space of the reactor 100 may be reduced, the amount of use of the substrate processing gas may also be reduced, and the above-described effects may be maximized by providing a top surface of the reactor 100 in a flat shape. Besides, durability of the reactor 100 may be increased by coupling the reinforcing ribs 120 or 130 to the top surface of the reactor 100.

According to the above descriptions of the embodiment of the present invention, discharge efficiency of a substrate processing gas may be increased by providing a horizontal cross-section of a reactor for processing substrates, in a shape having at least two curvature radii.

Furthermore, according to the embodiment of the present invention, deposition uniformity of the substrates may be increased by allowing the substrate processing gas to be discharged immediately after deposition reaction with the substrates.

In addition, according to the embodiment of the present invention, an internal space of the reactor may be reduced by modifying a top surface of the reactor from a bell shape into a flat shape.

While the present invention has been particularly shown and described with reference to embodiments thereof, it will be understood by those of ordinary skill in the art that various changes in form and details may be made therein without departing from the spirit and scope of the present invention as defined by the following claims.

What is claimed is:

1. A reactor of a substrate processing apparatus for processing at least one substrate, the reactor having a horizontal cross section provided in a shape having at least two curvature radii.

2. A reactor of a substrate processing apparatus for processing at least one substrate, the reactor having a horizontal cross section provided in a shape of at least two arcs having curvature radii greater than a diameter of the substrate.

3. A reactor of a substrate processing apparatus for processing at least one substrate, the reactor having a horizontal cross section provided in a shape of an oval having a minor axis greater than a diameter of the substrate.

4. The reactor of claim 1, comprising:
a substrate processor in which the substrate is processed;
a gas supplier for supplying a substrate processing gas into the substrate processor; and
a gas discharger for discharging the substrate processing gas supplied into the substrate processor.

5. The reactor of claim 4, wherein the gas discharger faces the gas supplier and is provided in a space between a circumferential portion of the substrate and an inner wall of the reactor.

6. The reactor of claim 4, wherein the gas supplier comprises:
at least one gas supply tube provided along a length direction of the gas supplier; and
a plurality of supply holes provided at a side of the gas supply tube and facing the substrate.

7. The reactor of claim 4, wherein the gas discharger comprises:
a gas discharge tube provided along a length direction of the gas discharger; and
a plurality of discharge holes provided at a side of the gas discharge tube and facing the substrate.

8. The reactor of claim 1, comprising a top surface,
wherein the top surface is flat.

9. The reactor of claim 8, wherein a plurality of reinforcing ribs are coupled to the top surface.

10. The reactor of claim 9, wherein the plurality of reinforcing ribs cross each other or are parallel with each other.

11. The reactor of claim 1, comprising at least one of quartz, stainless steel (SUS), aluminium, graphite, silicon carbide and aluminium oxide.

12. The reactor of claim 2, comprising:
a substrate processor in which the substrate is processed;
a gas supplier for supplying a substrate processing gas into the substrate processor; and
a gas discharger for discharging the substrate processing gas supplied into the substrate processor.

13. The reactor of claim 12, wherein the gas discharger faces the gas supplier and is provided in a space between a circumferential portion of the substrate and an inner wall of the reactor.

14. The reactor of claim 12, wherein the gas supplier comprises:
at least one gas supply tube provided along a length direction of the gas supplier; and
a plurality of supply holes provided at a side of the gas supply tube and facing the substrate.

15. The reactor of claim 12, wherein the gas discharger comprises:
a gas discharge tube provided along a length direction of the gas discharger; and
a plurality of discharge holes provided at a side of the gas discharge tube and facing the substrate.

16. The reactor of claim 3, comprising:
a substrate processor in which the substrate is processed;
a gas supplier for supplying a substrate processing gas into the substrate processor; and
a gas discharger for discharging the substrate processing gas supplied into the substrate processor.

17. The reactor of claim 16, wherein the gas discharger faces the gas supplier and is provided in a space between a circumferential portion of the substrate and an inner wall of the reactor.

18. The reactor of claim 16, wherein the gas supplier comprises:
at least one gas supply tube provided along a length direction of the gas supplier; and
a plurality of supply holes provided at a side of the gas supply tube and facing the substrate.

19. The reactor of claim 16, wherein the gas discharger comprises:
a gas discharge tube provided along a length direction of the gas discharger; and
a plurality of discharge holes provided at a side of the gas discharge tube and facing the substrate.

20. The reactor of claim 2, comprising a top surface,
wherein the top surface is flat.

21. The reactor of claim 20, wherein a plurality of reinforcing ribs are coupled to the top surface.

22. The reactor of claim 20, wherein the plurality of reinforcing ribs cross each other or are parallel with each other.

23. The reactor of claim 3, comprising a top surface,
wherein the top surface is flat.

24. The reactor of claim 23, wherein a plurality of reinforcing ribs are coupled to the top surface.

25. The reactor of claim 23, wherein the plurality of reinforcing ribs cross each other or are parallel with each other.

26. The reactor of claim 2, comprising at least one of quartz, stainless steel (SUS), aluminium, graphite, silicon carbide and aluminium oxide.

27. The reactor of claim 3, comprising at least one of quartz, stainless steel (SUS), aluminium, graphite, silicon carbide and aluminium oxide.
